(19) United States
(12) Patent Application Publication
(10) Pub. No.: US 2016/0013011 A1
(43) Pub. Date: Jan. 14, 2016

(54) ION IRRADIATION DEVICE AND ION IRRADIATION METHOD

(71) Applicant: ULVAC, Inc., Chigasaki-shi (JP)

(72) Inventors: Takumi YUZE, Chigasaki-shi (JP); Toshihiro TERASAWA, Chigasaki-shi (JP)

(73) Assignee: ULVAC, INC., Chigasaki-shi (JP)

(21) Appl. No.: 14/833,533

(22) Filed: Aug. 24, 2015

Related U.S. Application Data
(63) Continuation of application No. PCT/JP2015/055755, filed on Feb. 27, 2015.

(30) Foreign Application Priority Data
Mar. 12, 2014 (JP) 2014-048714

(51) Int. Cl. H01J 37/04

(52) U.S. Cl. CPC H01J 37/04

(57) ABSTRACT

Positive ions that fly within an ion acceleration tube are accelerated by a plurality of acceleration electrodes arranged within the ion acceleration tube and are irradiated to an irradiation target. A plurality of magnet devices is arranged within the ion acceleration tube; the directions of the lines of magnetic force formed respectively by the magnet devices are made to differ between the adjacent magnet devices by an angle of more than 0 degree and at most 90 degrees or less; and each of the lines of magnetic force is rotated in one direction within the ion acceleration tube. Electrons travelling in reverse within the ion acceleration tube are made to intersect the lines of magnetic force, and made to increase a distance from a flying axis while traveling in reverse. Since the electrons collide with members within the ion acceleration tube and stop before having high energy, high-energy X-rays are not generated.

This application is a continuation of International Application No. PCT/JP2015/55755, filed on Feb. 27, 2015, which claims priority to Japan Patent Application No. 2014-048714, filed on Mar. 12, 2014. The contents of the prior applications are herein incorporated by references in their entireties.

### BACKGROUND

The present invention relates to a technology for accelerating ions and particularly relates to a technology for accelerating ions without generating X-rays.

A technology for accelerating ions is used in an ion implantation device and a mass spectrometer. As in an ion acceleration device 116 shown in FIG. 7(a), a plurality of acceleration electrodes 102 shown in FIG. 6(a) is arranged within an ion acceleration tube 124.

It is assumed that in the ion acceleration device 116, the entrance side of ions at one end of a flight trajectory is the right side of the plane of the figure and that the emission side of ions at the other end of the flight trajectory is the left side of the plane of the figure.

Each of the acceleration electrodes 102 is a flat plate with a circular through hole 142 formed coaxially in the center of an electrode main body 141 whose outer circumference is circular; and within the ion acceleration tube 124, the acceleration electrodes 102 are aligned, with their surfaces facing each other perpendicularly to a center axis line 130 of the flight trajectory, in one row from the entrance side to the emission side.

Reference numeral 102S represents an acceleration electrode that is located closest to the entrance side; and reference numeral 102E represents an acceleration electrode that is located closest to the emission side.

An ion supplied from an ion generation source, on the entrance side, first enters the inside of a through hole 142 of the acceleration electrode 102S located closest to the entrance side, passes through the flight trajectory surrounded by the acceleration electrodes 102 in the middle, and is then emitted from the acceleration electrode 102E located closest to the emission side toward an irradiation target.

The ion accelerated by the ion acceleration device 116 is an ion having a positive charge; and a positive voltage is applied to the acceleration electrodes 102S, 102 and 102E.

A higher voltage is applied to the acceleration electrodes 102 and 102S closer to the entrance side among the acceleration electrodes 102S, 102 and 102E than the acceleration electrodes 102 and 102E located on the emission side; and when the ion travels along the flight trajectory surrounded by the electrode main bodies 141 from the entrance side to the emission side, the ion travels through an electric field formed by the acceleration electrodes 102, the ion is accelerated by a force from the electric field and its travel speed is significantly increased.

Although the inside of the ion acceleration tube 124 is vacuum-exhausted, some of the traveling ions may collide with a residual gas within the ion acceleration tube 124 or some of the traveling ions may collide with the acceleration electrodes 102 or the ion acceleration tube 124.

When the ion collides with the acceleration electrode 102, residual gas or the ion acceleration tube 124, electrons are emitted from the part where they collide with each other.

Since the charge of the emitted electron is negative, and has a polarity opposite to that of a positive ion, a force acting from the emission side toward the entrance side is applied, contrary to the ion, to the electron having entered the inside of the travel trajectory by the voltage applied to the acceleration electrodes 102S, 102 and 102E.

By this force, the electron travels, in reverse, along the travel trajectory from the emission side to the entrance side, and is accelerated, while travelling in reverse, by the electric field formed by the acceleration electrodes 102S, 102 and 102E, and as the travel distance is increased, the energy of the electron is increased.

Hence, when an ion collides with the acceleration electrodes 102 and 102E close to the emission side to generate an electron, and the electron travels in reverse along the travel trajectory and collides with the acceleration electrodes 102S and 102 close to the entrance side, since the electron travels a long distance to be accelerated by the electric field formed by a large number of acceleration electrodes 102E and 102, the electron becomes a high-speed electron (that is, a high-energy electron). When the such high-energy electron collides with the acceleration electrodes 102S and 102 or the ion acceleration tube 124, harmful high-energy X rays may be generated from the part where they collide with each other.

To cope with this problem, there is a method of arranging, as shown in FIGS. 6(b) and 7(b), acceleration electrodes 102a each having a magnet device 105 provided therein, instead of the acceleration electrodes 102S, 102 and 102E shown in FIG. 7(a), within the ion acceleration tube 124.

The magnet device 105 of the acceleration electrode 102a is arranged in a position on the electrode main body 141 with the through hole 142 interposed, and includes an N-pole facing magnet 105N where the N-pole is directed in the direction of the through hole 142 and an S-pole facing magnet 105S where the S-pole is directed therein; and within one magnet device 105, lines of magnetic force are formed between the N-pole facing magnet 105N and the S-pole facing magnet 105S, and particles passing through the through hole 142 are made to intersect the lines of magnetic force.

The N-pole facing magnets 105N in a plurality of magnet devices 105 located within the ion acceleration tube 124 are aligned on a straight line parallel to the center axis line 130 of the flight trajectory; the S-pole facing magnets 105S where the S-poles are directed to the flight trajectory are also aligned on a straight line parallel to the center axis line 130 of the flight trajectory; a Lorentz force in the same direction is applied to an electron flying along the flight trajectory; the flying direction of an electron having a small mass-to-charge ratio (mass/charge) is significantly curved and the electron collides with the acceleration electrode 102a or the ion acceleration tube 124 before traveling along distance to be accelerated to a high speed. Hence, the electron does not become a high-energy electron; and thus, high-energy X-rays are not generated. Cited references to the present invention are Japanese Patent Application Laid-Open Publication No. 6-5239 and Japanese Utility Model Application Laid-Open Publication No. 3-118600.

In recent years, high-energy ion irradiation has been demanded, and the potential difference between the acceleration electrodes 102a is increased to generate high-energy ions by an intense electric field.

However, in this case, when the potential difference is excessively increased, electrons travelling in reverse are significantly accelerated to emit high-energy X-rays.

In the attempt to cope with this problem, in the N-pole facing magnet 105N and the S-pole facing magnet 105S, magnets having a large magnetic force are used, the electrons are significantly curved and thus it is possible to reduce the emission of high-energy X-rays, since ions having a high energy and a large current are produced, some of the high-energy ions collide with the acceleration electrodes 102a, and thus, the acceleration electrodes 102a are heated. When the operating time of an ion acceleration device 216 becomes long, the time during which the N-pole facing magnet 105N and the S-pole facing magnet 105S are heated by the acceleration electrodes 102a becomes long, and the magnetic force is reduced, thereby resulting in the high-energy X-rays being emitted.

The present invention is made to solve the foregoing problem in the conventional technology; and an object thereof is to provide a technology that prevents generation of high-energy X-rays without increasing the magnetic force of a permanent magnet.

### SUMMARY OF THE INVENTION

To solve the above problem, according to the present invention, there is provided an ion irradiation device including: an ion source that generates a positive ion; and an ion acceleration device that flies, along a flight trajectory, the positive ion supplied from the ion source and entering an entrance side while accelerating the positive ion with acceleration electrodes aligned in a row and emits the positive ion from an emission side, the ion irradiation device irradiating an irradiation target with the accelerated positive ion, wherein the ion acceleration device includes a plurality of magnet devices each formed with a pair of an N-pole facing magnet whose N-pole surface is directed to the flight trajectory and an S-pole facing magnet whose S-pole surface is directed to the flight trajectory, in each of the magnet devices, the N-pole surface of the N-pole facing magnet and the S-pole surface of the S-pole facing magnet face each other with the flight trajectory therebetween, a directional vector extending from a center of the N-pole surface of the N-pole facing magnet toward a center of the S-pole surface of the S-pole facing magnet is perpendicular to a center axis line of the flight trajectory, a trajectory correction device including one of the magnet devices or adjacent two or more of the magnet devices whose directional vectors are apart from each other facing the same direction is configured, and the trajectory correction devices are arranged along the flight trajectory, and the directional vectors of the adjacent two trajectory correction devices among a plurality of the trajectory correction devices aligned in a row differ from each other in direction by a rotation angle of -more than 0 degree and at most 90 degrees or less; and when a direction of rotation is leftward or rightward, the trajectory correction devices are arranged such that the directional vectors of the trajectory correction devices aligned from the entrance side to the emission side are rotated either leftward or rightward in the same rotation direction.

According to the present invention, in the ion irradiation device, the rotation angles of the adjacent two trajectory correction devices are equal to each other.

According to the present invention, in the ion irradiation device, the rotation angle is set to 45 degrees, and each of the trajectory correction devices includes one of the magnet devices.

According to the present invention, in the ion irradiation device, the rotation angle is set to 90 degrees, and each of the trajectory correction devices includes one of the magnet devices.

According to the present invention, in the ion irradiation device, the rotation angle is set to 90 degrees, and each of the trajectory correction devices includes two of the magnet devices.

According to the present invention, in the ion irradiation device, each of the magnet devices is provided in a different one of the acceleration electrodes.

According to the present invention, there is provided an ion irradiation method of causing a positive ion produced in an ion source to enter an inside of an ion acceleration tube having a plurality of acceleration electrodes arranged therein, from an entrance side of the ion acceleration tube, accelerating the positive ion by the acceleration electrodes while flying the positive ion along a flight trajectory within the ion acceleration tube, emitting the positive ion from an emission side of the ion acceleration tube, and irradiating an irradiation target with the positive ion, the ion irradiation method including the steps of: forming a line of magnetic force intersecting the flight trajectory; applying a rotating force of a Lorentz force produced by the line of magnetic force to an electron that is generated within the ion acceleration tube and travels in a direction from the emission side toward the entrance side within the ion acceleration tube; causing the electron to increase a distance from a flying axis line which is a center axis line of the flight trajectory while traveling in the direction from the emission side toward the entrance side within the ion acceleration tube; and causing the electron to collide with a member within the ion acceleration tube and stop.

According to the present invention, there is provided the ion irradiation method of sequentially aligning magnet devices one by one between the entrance side and the emission side, causing an N-pole surface of an N-pole facing magnet and an S-pole surface of an S-pole facing magnet included in each of the magnet devices to face each other, forming lines of magnetic force between the N-pole surfaces and the S-pole surfaces, respectively, and causing the electron to intersect the line of magnetic force and generate a Lorentz force, wherein a direction of a directional vector extending from a center of the N-pole surface toward a center of the S-pole surface in the magnet device is made to differ between the adjacent two magnet devices by an angle more than 0 degrees and at most 90 degrees or less, and the line of magnetic force formed by the adjacent magnet devices is rotated in one direction between the entrance side and the emission side.

According to the present invention, there is provided the ion irradiation method, wherein an N-pole surface of an N-pole facing magnet and an S-pole surface of an S-pole facing magnet in a plurality of magnet devices formed with a pair of the N-pole facing magnet whose N-pole surface is directed to the flight trajectory and the S-pole facing magnet whose S-pole surface is directed to the flight trajectory are arranged facing each other with the flight trajectory therebetween, a directional vector extending from a center of the N-pole surface of the N-pole facing magnet toward a center of the S-pole surface of the S-pole facing magnet is made perpendicular to a center axis line of the flight trajectory, a trajectory correction device including one of the magnet devices or adjacent two or more of the magnet devices whose directional vectors are apart from each other facing the same direction are arranged along the flight trajectory, the directional vectors of the adjacent two trajectory correction devices among a plurality of the trajectory correction devices aligned in a row are made to differ from each other by a predetermined rotation angle of more than 0 degree and at most 90 degrees or less; and when a direction of rotation is leftward or rightward, each of the trajectory correction devices is arranged such that the directional vectors of the trajectory correction devices aligned from the entrance side to the emission side are rotated either leftward or rightward in the same rotation direction.

According to the present invention, in the ion irradiation method, the rotation angles of the trajectory correction devices are equal to each other.

According to the present invention, in the ion irradiation method, the rotation angle is set to 45 degrees, and in each of the trajectory correction devices, one of the magnet devices is provided.

According to the present invention, in the ion irradiation method, the rotation angle is set to 90 degrees, and in each of the trajectory correction devices, one of the magnet devices is provided.

According to the present invention, in the ion irradiation method, the rotation angle is set to 90 degrees, and in each of the trajectory correction devices, two of the magnet devices are provided.

According to the present invention, in the ion irradiation method, each of the magnet devices is provided in a different one of the acceleration electrodes.

The lines of magnetic force formed by trajectory correction devices aligned in a row are rotated in a given rotation direction, a rotating force of a Lorentz force is applied to electrons generated on an emission side while the electrons travel in reverse from the emission side to an entrance side and since the electrons travel in reverse while increasing a distance from a flying axis line which is a center axis line of the flight trajectory, the electrons travelling in reverse are more likely to be moved out of the flight trajectory. Hence, the electrons collide with an acceleration electrode or an acceleration tube before traveling in reverse a long distance. Since the electrons travelling in reverse collide with it when its travel speed is low, high-energy X-rays are not generated.

### BRIEF DESCRIPTION OF THE DRAWINGS

FIG. 1 is a diagram for illustrating an ion irradiation device of the present invention.

FIGS. 2(a) to 2(h) are examples of an acceleration electrode that can be used in the ion irradiation device.

FIG. 3 is an example of an ion acceleration tube in which a trajectory correction device is formed with one acceleration electrode; and the directional vectors of the adjacent trajectory correction devices are rotated rightwardly by 45 degrees.

FIG. 4 is an example of an ion acceleration tube in which a trajectory correction device is formed with one acceleration electrode, and the directional vectors of the adjacent trajectory correction devices are rotated rightwardly by 90 degrees.

FIG. 5 is an example of an ion acceleration tube in which a trajectory correction device is formed with two acceleration electrodes; and the directional vectors of the adjacent trajectory correction devices are rotated rightwardly by 90 degrees.

FIGS. 6(a) and 6(b) are examples of an acceleration electrode in a conventional technology.

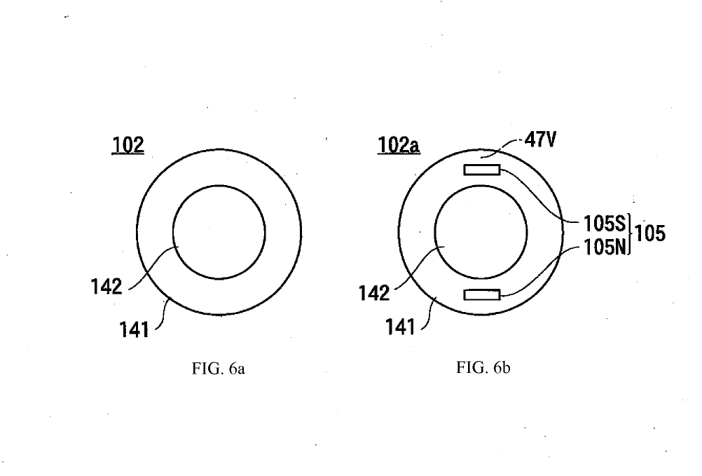

FIGS. 7(a) and 7(b) are ion acceleration devices using the acceleration electrode in the conventional technology.

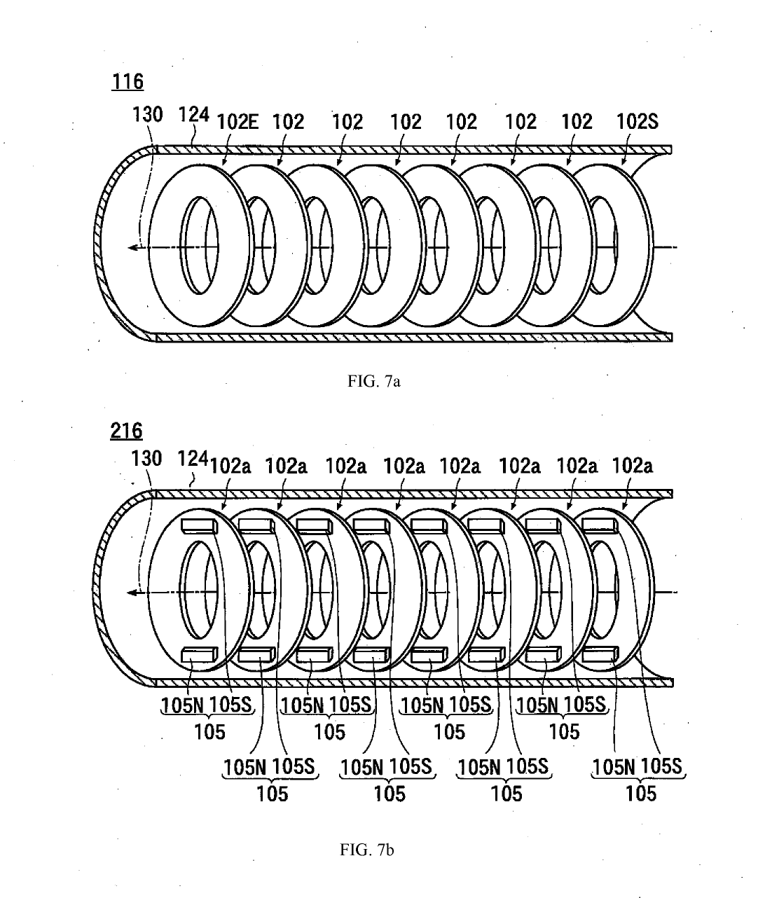

### DETAILED DESCRIPTION OF THE INVENTION

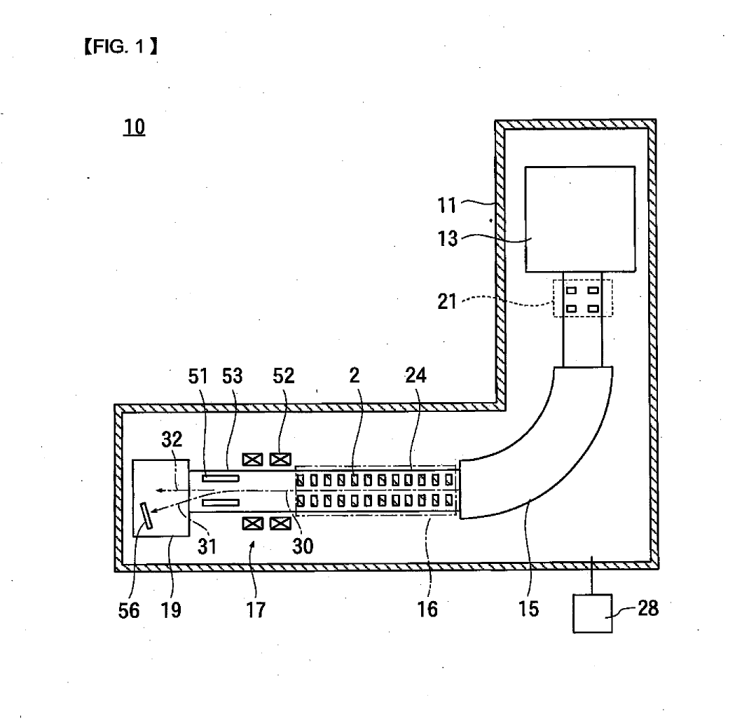

Reference numeral 10 in FIG. 1 represents an example of an ion irradiation device of the present invention.

An ion irradiation device 10 includes devices (such as an ion implantation device and a measurement device) that accelerate positive ions to irradiate an irradiation target with the positive ions.

The ion irradiation device 10 includes a vacuum tank 11; and the inside of the vacuum tank 11 is vacuum-exhausted by a vacuum exhaust device 28 and is placed in a vacuum atmosphere.

Within the vacuum tank 11, an ion source 13 that produces positive ions, an ion drawing portion 21 that draws the positive ions produced by the ion source 13 and a mass spectrometer 15 that performs mass analysis on the positive ions drawn by the ion drawing portion 21 and passes positive ions having a desired mass-to-charge ratio.

The flow of the positive ions analyzed by the mass spectrometer 15 is supplied to an ion acceleration device 16 arranged on the downstream side of the mass spectrometer 15.

The positive ion supplied from the mass spectrometer 15 is accelerated within the ion acceleration device 16, the travel direction of the positive ion is curved by magnetic force filters 52 and electric field filers 51 which are provided in a travel direction change device 17 and are arranged outside or inside a tube 53 and an irradiation target 56 located on an extended line in the travel direction is irradiated with the positive ion.

The travel direction of a neutral particle having entered the inside of the travel direction change device 17 is not curved by the magnetic force filters 52 and the electric field filers 51; and the neutral particle travels linearly and is not irradiated to the irradiation target 56.

Reference numeral 31 in FIG. 1 represents the travel direction of the positive ion, and reference numeral 32 represents the travel direction of the neutral particle.

A description will be given of the ion acceleration device 16. The ion acceleration device 16 includes an ion acceleration tube 24 through which the positive ion passes, and a plurality of acceleration electrodes 2 is arranged therewithin.

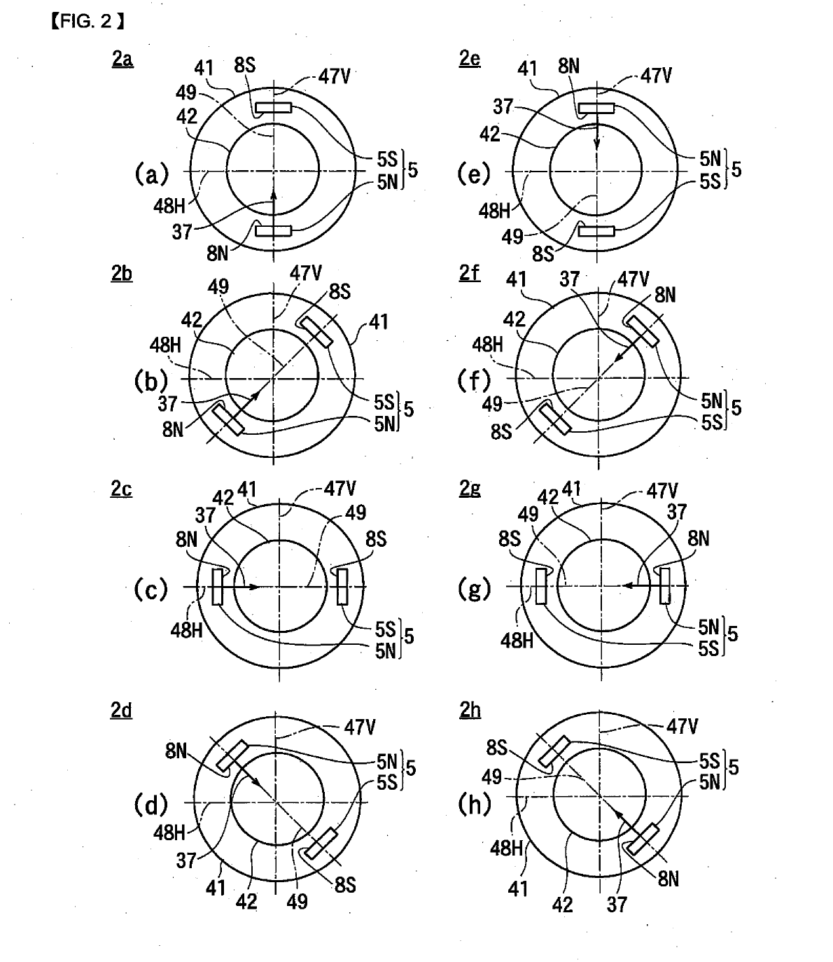

Reference numerals 2a to 2h shown in FIGS. 2(a) to 2(h) represent the plurality of acceleration electrodes 2 located within the ion acceleration tube 24, and since they have the same structure, a description will be given of the structure by use of numeral 2.

Each acceleration electrode 2 includes an annular electrode main body 41 which is a flat plate and has a circular outer circumference and a circular through hole 42 which is formed in the center position of the electrode main body 41. In the electrode main body 41 of each acceleration electrode 2, one magnet device 5 is provided.

The magnet device 5 includes an N-pole facing magnet 5N and an S-pole facing magnet 5S.

The N-pole facing magnet 5N and the S-pole facing magnet 5S of the magnet device 5 are arranged on the same surface side of the same electrode main body 41, and are fixed to positions of the electrode main body 41 opposite to each other such that the through hole 42 is located in the center between the N-pole facing magnet 5N and the S-pole facing magnet 5S and an N-pole surface 8N on which the N-pole of the N-pole facing magnet 5N is arranged and an S-pole surface 8S on which the S-pole of the S-pole facing magnet 5S is arranged are arranged facing each other.

Hence, the N-pole surface 8N and the S-pole surface 8S are directed toward the positions near above the through hole 42 respectively, and the lines of magnetic force formed between the N-pole surface 8N and the S-pole surface 8S are located parallel to the surface of the through hole 42 and over the surface of the through hole 42.

Here, the length of the N-pole facing magnet 5N and the length of the S-pole facing magnet 5S are substantially equal to the diameter of the through hole 42, and particles passing through the through hole 42 intersect the lines of magnetic force formed between the N-pole surface 8N and the S-pole surface 8S.

The plurality of acceleration electrodes 2 arranged within the ion acceleration tube 24 is arranged such that the electrode main bodies 41 thereof are parallel to each other and that the center points of the through holes 42 are aligned in a straight line within the ion acceleration tube 24; and thus, a cylindrical space formed so as to penetrate the through holes 42 of the plurality of acceleration electrodes 2 arranged within the ion acceleration tube 24 serves as the travel trajectory along which the positive ions and the electrons pass.

The centers of the through holes 42 of the acceleration electrodes 2 are arranged in a row on a travel axis line 30, which is the center axis line of the travel trajectory; and the electrode main bodies 41 are perpendicular to the travel axis line 30 of the travel trajectory.

Hence, the travel trajectory is surrounded by the electrode main bodies 41 of the acceleration electrodes 2, and a positive voltage is applied to the acceleration electrodes 2.

When it is assumed that one of both ends of the ion acceleration tube 24 through which the positive ion enters the ion acceleration tube 24 is an entrance side and that the other end through which the positive ion is emitted is an emission side, with respect to the potentials of the acceleration electrodes 2 within the ion acceleration tube 24, the acceleration electrode 2 located on the entrance side has a higher potential than the other acceleration electrodes 2 located on the emission side relative to the acceleration electrode 2, and an electric field is formed within the ion acceleration tube 24 by the acceleration electrodes 2.

Hence, the positive ion having entered the entrance side of the travel trajectory from the mass spectrometer 15 is accelerated toward the emission side by the electric field formed by the acceleration electrodes 2, and the travel speed thereof is increased as the positive ion passes through the acceleration electrodes 2.

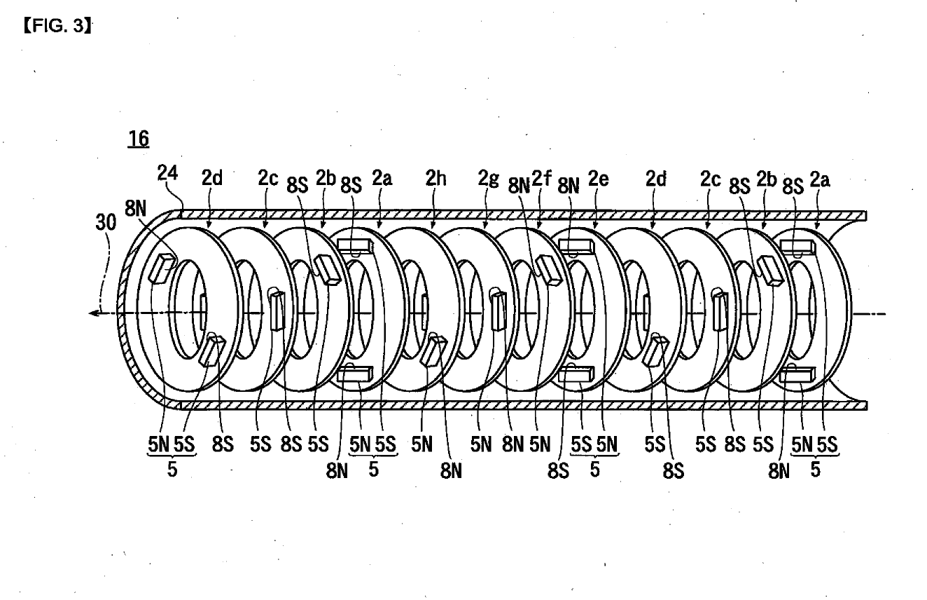

In among a plurality of acceleration electrodes 2 arranged within the ion acceleration tube 24 of the ion acceleration device 16 shown in FIG. 3, a predetermined number of acceleration electrodes 2 arranged sequentially one by one from the entrance side toward the emission side are assumed to be an acceleration electrode pair; and within the ion acceleration tube 24 of this example, one or more acceleration electrode pairs are arranged. In FIGS. 2(a) to 2(h), acceleration electrodes 2a to 2h including in one acceleration electrode pair are shown.

The acceleration electrodes 2a to 2h have the same structure, and differ from each other only in the relative positions of the N-pole facing magnet 5N and the S-pole facing magnet 5S. It is assumed that the acceleration electrode of the first reference numeral 2a is on the emission side and that the acceleration electrode of the last reference numeral 2h is on the entrance side; and they are aligned sequentially one by one.

Here, the center axis line of the through holes 42 of the acceleration electrodes 2a to 2h and the straight line passing through the N-pole facing magnet 5N and the S-pole facing magnet 5S are rotated by a predetermined angle among the adjacent acceleration electrodes 2a to 2h. The rotation is performed in the same direction from the emission side toward the entrance side.

When the acceleration electrodes 2 of a plurality of acceleration electrode pairs are arranged within the ion acceleration tube 24, on the entrance side of the acceleration electrode 2h closest to the entrance side of the acceleration electrode pair located on the ion emission side of the adjacent acceleration electrode pairs, the acceleration electrode 2a closest to the emission side of the acceleration electrode pair on the entrance side is arranged.

Reference numeral 37 in FIGS. 2(a) to 2(h) represents a directional vector that is directed from the center of the N-pole surface 8N toward the center of the S-pole surface 8S, and indicates the direction of the lines of magnetic force formed between the N-pole surface 8N and the S-pole surface 8S in one magnet device 5. Since the acceleration electrodes 2a to 2h are parallel, the planes on which the direction vectors of the acceleration electrodes 2a to 2h are located are parallel.

Here, it is assumed that the travel axis line 30 of the flight trajectory is arranged horizontally, that the electrode main bodies 41 of the acceleration electrodes 2a to 2h are arranged vertically, that the positions of the N-pole facing magnet 5N and the S-pole facing magnet 5S are represented by the center positions of the N-pole surface 8N and the S-pole surface 8S, and that the center positions are identified as positions of the dial face of a wall clock to indicate the positions of the N-pole facing magnet 5N and the S-pole facing magnet 5S.

In this case, when it is assumed that the starting point of the directional vector 37 of each of the acceleration electrodes 2a to 2h is moved to the center of the through hole 42 and the directional vector 37 is regarded as the dial of the clock, the dial indicates the time where the center of the S-pole surface 8S is located.

More particularly, when it is assumed that in the acceleration electrode 2a is as shown in FIG. 2(a), the center of the N-pole surface 8N is located at six o'clock, the center of the S-pole surface 8S is located at twelve o'clock (zero o'clock), and the directional vector indicates the zero o'clock (twelve o'clock); and thus, the directional vector 37 of each of the acceleration electrodes 2a to 2h is identified, first, in the acceleration electrode 2b of FIG. 2(b), the center of the N-pole surface 8N is located at half past seven, the S-pole surface 8S is located at half past one and the directional vector 37 thereof indicates half past one.

Hence, the directional vector 37 of the acceleration electrode 2b arranged in the second place is inclined at an angle of 45 degrees right-handed (clockwise) with respect to the directional vector 37 of the acceleration electrode 2a arranged in the first place.

In the electrodes 2c to 2h in the third and subsequent places, the N-pole surface 8N is located at nine o'clock, at half past ten, at twelve o'clock (zero o'clock), at half past one, at three o'clock and at half past four, respectively, the S-pole surface 8S is located at three o'clock, at half past four, at six o'clock, at half past seven, at nine o'clock and at half past ten, respectively; and the directional vector 37 indicates three o'clock, half past four, six o'clock, half past seven, nine o'clock and half past ten, respectively. After the acceleration electrode 2h arranged in the last place, the first acceleration electrode 2a is arranged.

Among the acceleration electrodes 2a to 2h and 2a inside the ion acceleration tube 24, in the directional vectors 37 of the adjacent acceleration electrode 2a to 2h, the output side is ahead of the entrance side by one and a half hours and is inclined at an angle of 45 degrees right-handed.

In order to uniformly arrange the directional vectors over an angle of one revolution of 360 degrees, the acceleration electrodes 2 of eight pieces obtained by dividing the angle of one revolution of 360 degrees by the angle (45 degrees) between the dials adjacent to each other are needed.

The electron that travels along the travel trajectory surrounded by the acceleration electrodes 2a to 2h arranged, as described above, intersects, at a substantially perpendicular angle, the lines of magnetic force formed between the N-pole surface 8N and the S-pole surface 8S facing each other within the magnet device 5; and a Lorentz force in a direction perpendicular to the travel axis line 30 is applied to the electron.

In the ion acceleration device 16 shown in FIG. 3, the directional vector 37 is rotated rightwardly from the entrance side to the emission side; and a Lorentz force applied from the magnet device 5 provided in each of the acceleration electrodes 2a to 2h to the charged particles (ions and electrons) moving along the travel trajectory acts in a radial direction of a circle perpendicularly intersecting the travel axis line 30 with the travel axis line 30 in the center. The Lorentz force is rotated in the same direction as the direction of rotation of the directional vector 37 as the directional vector 37 is rotated.

Hence, the acceleration electrodes 2a to 2h with directional vectors 37 that are rotated apply, to the electron travelling in reverse along the flight trajectory, such a Lorentz force that moves the electron in a helical manner in which the rotation radius is gradually increased, with the result that the electron travels in reverse only a short distance within the ion acceleration tube 24, and moves out of the flight trajectory to collide with the internal members of the ion acceleration tube 24 such as the acceleration electrodes 2a to 2h and the surface of the ion acceleration tube 24 and stops.

Since an ion has a larger mass than an electron, the effect of the Lorentz force on the magnet device 5 is small, and thus it is possible to ignore the effect.

As described above, in the ion irradiation device 10 of the present invention, since the electron does not travel in reverse a long distance along the travel trajectory and stops, high-speed electrons are not produced; and thus, high-energy X-rays are not emitted.

Since a rotating force is also applied to an electron having entered in an oblique direction with respect to the travel axis line 30, an electron that enters in any direction to travel in reverse is more likely to be moved out of the travel trajectory.

Although the directional vector 37 of each of the magnet devices 5 arranged within the ion acceleration tube 24 may be rotated rightwardly as described above or may be alternatively rotated leftwardly (counterclockwise), the direction of rotation of the directional vector 37 in one ion acceleration tube 24 is preferably one direction of either the rightward rotation or the leftward rotation. It is undesirable that the rightward rotation and the leftward rotation are mixed because magnetic fields on the travel trajectory interfere with each other, the vertical component of the magnetic field is reduced, the rotation radius of the electron is reduced and the number of electrons passing through to the upstream side is increased.

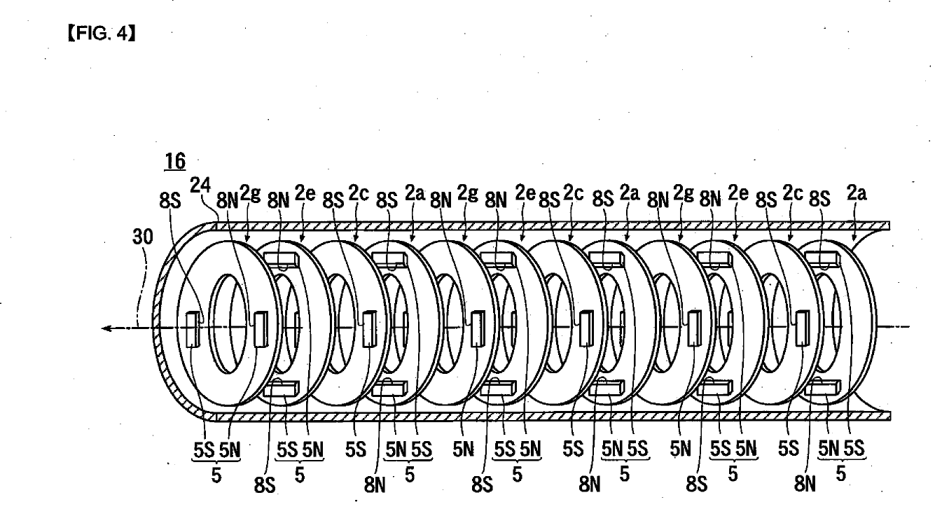

Although the above description deals with the case where the directional vectors 37 of the adjacent acceleration electrodes 2a to 2h and 2a are rotated rightwardly while the angles thereof are made to differ from each other by 45 degrees, the difference of the angles is not limited to 45 degrees. For example, when as shown in FIG. 4, the acceleration electrodes 2a, 2c, 2e and 2g with directional vectors 37 that indicate twelve o'clock (zero o'clock), three o'clock, six o'clock and nine o'clock respectively are repeatedly arranged in this order a necessary number of times as shown in FIG. 4, the angles of the directional vectors of the adjacent acceleration electrodes 2a, 2c, 2e and 2g differ from each other by 90 degrees in the rightward rotation.

Even in this case, an electron receives a force in the same direction to be moved out of the travel trajectory, collides with, even before having a high energy, the internal members of the ion acceleration tube 24 and stops.

Although the above description deals with the case where among a plurality of acceleration electrodes 2 arranged within the ion acceleration tube 24, the directions of the directional vectors 37 of the adjacent acceleration electrodes 2 differ from each other by a predetermined angle, a plurality of acceleration electrodes 2 that has directional vectors 37 facing the same direction and that are adjacent to each other are used as trajectory correction devices, and a plurality of trajectory correction devices can be arranged within the ion acceleration tube 24.

Preferably, even in this case, the acceleration electrodes 2 provided in the trajectory correction devices are vertical with respect to the travel axis line 30, the centers of the through holes 42 are located on the flying axis line 30 and the directional vectors 37 of the trajectory correction devices aligned from one of the entrance side and the emission side toward the other are rotated in one direction. In order to minimize effects on ion beams, the directional vector is preferably set to be an integral multiple of the 360-degree rotation.

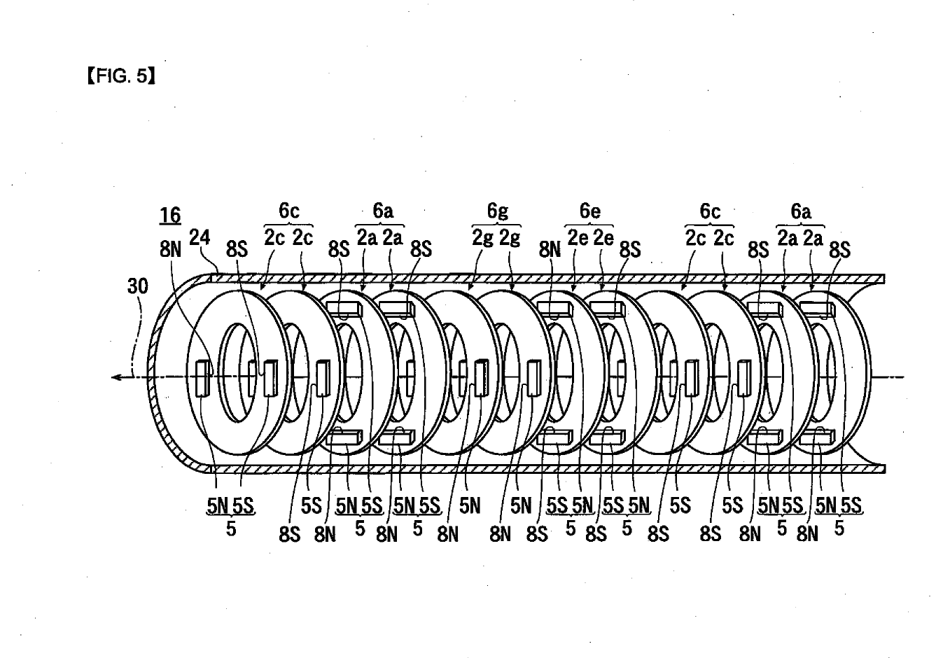

In the ion acceleration device 16 of FIG. 5, trajectory correction devices 6a, 6c, 6e and 6g are formed with two acceleration electrodes 2a, 2c, 2e and 2g with directional vectors 37 that are directed in the same direction, and within the ion acceleration tube 24, the directional vectors 37 of the adjacent trajectory correction devices 6a, 6c, 6e and 6g differ from each other by 90 degrees, and are rotated rightwardly from the entrance side toward the emission side.

In the ion acceleration device 16 of FIG. 5, as compared with a case where among the trajectory correction devices 6a, 6c, 6e and 6g, each of the acceleration electrodes 2a, 2c, 2e and 2g is used as the trajectory correction device, the number of lines of magnetic force between the N-pole surface 8N and the S-pole surface 8S is increased, and the effects of the adjacent trajectory correction devices 6a, 6c, 6e and 6g are reduced.

Furthermore, in the ion acceleration device 16 shown in FIGS. 3 and 4, one trajectory correction device is assumed to be formed with the acceleration electrodes 2a to 2h or the acceleration electrodes 2a, 2c, 2e and 2g, and within the ion acceleration tube 24, the trajectory correction devices rotated in one direction can be arranged.

Although in the example described above, the directional vectors 37 of the adjacent acceleration electrodes 2 differ from each other by 45 or 90 degrees, the relative rotation angle of the adjacent acceleration electrodes 2 can be set such that they differ from each other by an angle of not less than 0 degree and not more than 90 degrees.

Although in the example described above, the sizes of the electrode main bodies 41 of the adjacent acceleration electrodes 2 are equal to each other, the sizes of the through holes 42 are also equal to each other and the acceleration electrodes 2 are arranged at regular intervals, the present invention is not limited to such a configuration. A configuration where the acceleration electrodes 2 in which the sizes of the electrode main bodies 41 and the through holes 42 differ from each other are arranged is also included in the present invention.

Although in the example described above, the lengths of the N-pole facing magnet 5N and the S-pole facing magnet 5S are substantially equal to the diameter of the through hole 42, as long as an ion is prevented from directly colliding with the N-pole facing magnet 5N and the S-pole facing magnet 5S, the lengths of the N-pole facing magnet 5N and the S-pole facing magnet 5S may be longer than the diameter of the through hole or may be longer than the outer circumferential diameter of the electrode main body 41. Alternatively, as long as an electron passing through the through hole 42 intersects the lines of magnetic force formed between the N-pole surface 8N and the S-pole surface 8S of the N-pole facing magnet 5N and the S-pole facing magnet 5S arranged near the through hole 42, the lengths of the N-pole facing magnet 5N and the S-pole facing magnet 5S may be shorter than the diameter of the through hole 42.

Moreover, although in the example described above, the N-pole facing magnet 5N and the S-pole facing magnet 5S are provided on the surface facing the emission side of the acceleration electrodes 2, in the present invention, as long as the lines of magnetic force formed between the N-pole facing magnet 5N and the S-pole facing magnet 5S can be arranged to be vertical with respect to the travel axis line 30, and an electron passing through the through hole 42 can be arranged to intersect the lines of magnetic force formed between the N-pole surface 8N and the S-pole surface 8S, the N-pole facing magnet 5N and the S-pole facing magnet 5S do not necessarily need to be provided in the acceleration electrodes 2, and for example, the N-pole facing magnet 5N and the S-pole facing magnet 5S may be fixed to a holding device fixed to the ion acceleration tube 24.

Furthermore, although an ion traveling along the travel trajectory also intersects the lines of magnetic force formed by the magnet devices 5 to receive a Lorentz force, since the mass-to-charge ratio of the ion is extremely larger than that of the electron, its effect is small.

Although in the example described above, the directional vectors of the adjacent trajectory correction devices differ from each other by 45 or 90 degrees, when the angle is larger than 0 degree but is as small as possible, since a decrease in the vertical magnetic field component on the travel trajectory caused by an interference of the lines of magnetic force between the adjacent trajectory correction devices having different directional vectors is reduced, it is possible to effectively restrain the reverse flow of electrons. Since in order to minimize the effect on low-speed ion beams, the directional vector is preferably an integral multiple of the 360-degree rotation, when the angle of the directional vectors of the trajectory correction devices is small, it is necessary to increase the number of trajectory correction devices.

On the other hand, when the angle of the directional vectors of the adjacent trajectory correction devices exceeds 90 degrees, since the effects of the magnets cancel each other, it is difficult to apply a Lorentz force to an electron to sufficiently increase the distance from the travel axis line.

Hence, the angle of the directional vectors of the adjacent trajectory correction devices, when expressed as a positive number, needs to be more than 0 degree and at most 90 degrees or less.

### EXPLANATION OF REFERENCE NUMERALS

2, 2a to 2h acceleration electrode
5 magnet device
5N N-pole facing magnet
5S S-pole facing magnet
6a, 6c, 6e, 6g trajectory correction device
8N N-pole surface
8S S-pole surface
10 ion irradiation device
13 ion source
16 ion acceleration device
24 ion acceleration tube
30 center axis line of travel trajectory
37 directional vector

What is claimed is:

1. An ion irradiation device, comprising:
an ion source that generates a positive ion; and
an ion acceleration device that travel, along a flight trajectory, the positive ion supplied from the ion source and entering an entrance side while accelerating the positive ion with acceleration electrodes aligned in a row and emits the positive ion from an emission side,
the ion irradiation device irradiating an irradiation target with the accelerated positive ion,
wherein the ion acceleration device includes a plurality of magnet devices each formed with a pair of an N-pole facing magnet whose N-pole surface is directed to the travel trajectory and an S-pole facing magnet whose S-pole surface is directed to the travel trajectory,
in each of the magnet devices, the N-pole surface of the N-pole facing magnet and the S-pole surface of the S-pole facing magnet face each other with the travel trajectory therebetween,
a directional vector extending from a center of the N-pole surface of the N-pole facing magnet toward a center of the S-pole surface of the S-pole facing magnet is perpendicular to a center axis line of the travel trajectory,
a trajectory correction device including one of the magnet devices or at least two adjacent magnet devices with directional vectors that are apart from each other facing the same direction is configured, and the trajectory correction devices are arranged along the travel trajectory, and
the directional vectors of the adjacent two trajectory correction devices among a plurality of the trajectory correction devices aligned in a row differ from each other in direction by a rotation angle more than 0 degree and at most 90 degrees or less, and when a direction of rotation is leftward or rightward, the trajectory correction devices are arranged such that the directional vectors of the trajectory correction devices aligned from the entrance side to the emission side are rotated either leftward or rightward in the same rotation direction.

2. The ion irradiation device according to claim 1,
wherein the rotation angles of the adjacent two trajectory correction devices are equal to each other.

3. The ion irradiation device according to claim 1,
wherein the rotation angle is set to 45 degrees, and each of the trajectory correction devices includes one of the magnet devices.

4. The ion irradiation device according to claim 1,
wherein the rotation angle is set to 90 degrees, and each of the trajectory correction devices includes one of the magnet devices.

5. The ion irradiation device according to claim 1,
wherein the rotation angle is set to 90 degrees, and each of the trajectory correction devices includes two of the magnet devices.

6. The ion irradiation device according to claim 1,
wherein each of the magnet devices is provided in a different one of the acceleration electrodes.

7. An ion irradiation method of causing a positive ion produced in an ion source to enter an inside of an ion acceleration tube having a plurality of acceleration electrodes arranged therein, from an entrance side of the ion acceleration tube, accelerating the positive ion by the acceleration electrodes while traveling the positive ion along a travel trajectory within the ion acceleration tube, emitting the positive ion from an emission side of the ion acceleration tube, and irradiating an irradiation target with the positive ion, the ion irradiation method comprising the steps of:
forming a line of magnetic force intersecting the travel trajectory;
applying a rotating force of a Lorentz force produced by the line of magnetic force to an electron that is generated within the ion acceleration tube and travels in a direction from the emission side toward the entrance side within the ion acceleration tube;
causing the electron to increase a distance from a travel axis line which is a center axis line of the travel trajectory while traveling in the direction from the emission side toward the entrance side within the ion acceleration tube;
and causing the electron to collide with a member within the ion acceleration tube and stop.

8. The ion irradiation method according to claim 7, of sequentially aligning magnet devices one by one between the entrance side and the emission side, causing an N-pole surface of an N-pole facing magnet and an S-pole surface of an S-pole facing magnet included in each of the magnet devices to face each other, forming lines of magnetic force between the N-pole surfaces and the S-pole surfaces, respectively, and causing the electron to intersect the line of magnetic force and generate a Lorentz force,
wherein a direction of a directional vector extending from a center of the N-pole surface toward a center of the S-pole surface in the magnet device is made to differ between the adjacent two magnet devices by an angle more than 0 degree and at most 90 degrees or less, and
wherein the line of magnetic force formed by the adjacent magnet devices is rotated in one direction between the entrance side and the emission side.

9. The ion irradiation method according to claim 7,
wherein an N-pole surface of an N-pole facing magnet and an S-pole surface of an S-pole facing magnet in a plurality of magnet devices formed with a pair of the N-pole facing magnet whose N-pole surface is directed to the flight trajectory and the S-pole facing magnet with the S-pole surface directed to the travel trajectory are arranged facing each other with the travel trajectory therebetween,
wherein a directional vector extending from a center of the N-pole surface of the N-pole facing magnet toward a center of the S-pole surface of the S-pole facing magnet is made perpendicular to a center axis line of the flight trajectory,
wherein a trajectory correction device including one of the magnet devices or at least two adjacent magnet devices having directional vectors are apart from each other facing the same direction are arranged along the travel trajectory,
wherein the directional vectors of the adjacent two trajectory correction devices among a plurality of the trajectory correction devices aligned in a row are made to differ from each other by a predetermined rotation angle by more than 0 degree and at most 90 degrees or less, and
wherein when a direction of rotation is leftward or rightward, each of the trajectory correction devices is arranged such that the directional vectors of the trajectory correction devices aligned from the entrance side to the emission side are rotated either leftward or rightward in the same rotation direction.

10. The ion irradiation method according to claim 9,
wherein the rotation angles of the trajectory correction devices are equal to each other.

11. The ion irradiation method according to claim 10,
wherein the rotation angle is set to 45 degrees, and in each of the trajectory correction devices, one of the magnet devices is provided.

12. The ion irradiation method according to claim 10,
wherein the rotation angle is set to 90 degrees, and in each of the trajectory correction devices, one of the magnet devices is provided.

13. The ion irradiation method according to claim 10,
wherein the rotation angle is set to 90 degrees, and in each of the trajectory correction devices, two of the magnet devices are provided.

14. The ion irradiation method according to claim 7,
wherein each of the magnet devices is provided in a different one of the acceleration electrodes.
